(19) United States
(12) Patent Application Publication
(10) Pub. No.: US 2012/0093185 A1
(43) Pub. Date: Apr. 19, 2012

(54) METHOD FOR MANUFACTURING SEMICONDUCTOR LASER APPARATUS, SEMICONDUCTOR LASER APPARATUS, AND OPTICAL APPARATUS

(75) Inventors: Gen Shimizu, Tottori-shi (JP); Shinichiro Akiyoshi, Kurayoshi-shi (JP)

(73) Assignees: SANYO Optec Design Co., Ltd., Bunkyo-ku (JP); Sanyo Electric Co., Ltd., Moriguchi-shi (JP)

(21) Appl. No.: 13/252,487

(22) Filed: Oct. 4, 2011

(30) Foreign Application Priority Data
Oct. 15, 2010 (JP) 2010-232796

(51) Int. Cl. H01S 5/40; B23K 1/20; B23K 31/02

(52) U.S. Cl. 372/43.01; 228/179.1

(57) ABSTRACT

This method for manufacturing a semiconductor laser apparatus includes steps of forming a first semiconductor laser device having a first electrode, forming a second semiconductor laser device having a second electrode, forming a first solder layer with a first melting point through a first barrier layer on a third electrode, forming a second solder layer with a second melting point through a second barrier layer on a fourth electrode, bonding the first electrode to the third electrode through a first reaction solder layer, a melting point of which rises to a third melting point higher than the second melting point by reacting the first electrode with the first solder layer, and bonding the second electrode to the fourth electrode by applying heat of a first heating temperature to melt the second solder layer with the second melting point after the step of bonding the first electrode to the third electrode.

### CROSS-REFERENCE TO RELATED APPLICATIONS

The priority application number JP2010-232796, Method for Manufacturing Semiconductor Laser Apparatus, Semiconductor Laser Apparatus, and Optical Apparatus, Oct. 15, 2010, Gen Shimizu et al., upon which this patent application is based, is hereby incorporated by reference.

### BACKGROUND OF THE INVENTION

1. Field of the Invention

The present invention relates to a method for manufacturing a semiconductor laser apparatus, a semiconductor laser apparatus, and an optical apparatus, and more particularly, it relates to a method for manufacturing a semiconductor laser apparatus having a first semiconductor laser device and a second semiconductor laser device both bonded to a base, a semiconductor laser apparatus, and an optical apparatus.

2. Description of the Background Art

A method for manufacturing a semiconductor laser apparatus having a first semiconductor laser device and a second semiconductor laser device both bonded to a base is known in general, as disclosed in Japanese Patent Laying-Open No. 2000-268387, for example.

Japanese Patent Laying-Open No. 2000-268387 discloses a semiconductor light source module having light source chips bonded to the upper surface of a silicon substrate with different types of solder having different melting points from each other. A method for manufacturing this semiconductor light source module includes steps of applying first solder (solder having a higher melting point) and second solder (solder having a lower melting point) onto a pair of metal plating layers of Au or the like formed on the upper surface of the silicon substrate, bonding a first light source chip to the silicon substrate with the first solder melted by applying heat of 300° C. in a state where the first light source chip is arranged on the first solder (solder having a higher melting point), and bonding a second light source chip to the silicon substrate with the second solder melted by applying heat of 200° C. in a state where the second light source chip is arranged on the second solder (solder having a lower melting point) having a lower melting point than the first solder after bonding the first light source chip to the silicon substrate. In this method for manufacturing the semiconductor light source module, not only the first solder but also the second solder employed in the later bonding step are melted when the first light source chip is bonded to the silicon substrate.

In the method for manufacturing the semiconductor light source module disclosed in Japanese Patent Laying-Open No. 2000-268387, however, not only the first solder (solder having a higher melting point) but also the second solder (solder having a lower melting point) are melted when the first light source chip is bonded to the silicon substrate, and hence the melted second solder and the metal plating layer on a lower portion of the second solder may conceivably react and be alloyed with each other. Thus, the melting point of a metal layer after alloying may be rendered higher than the melting point of the metal layer before alloying if a composition of individual metal materials constituting the metal layer (alloy layer) made of at least two materials is changed due to alloying of the metal layer. In this case, the second solder must be heated at higher temperature and melted when the second light source chip is bonded to the silicon substrate, and hence thermal stress generated in the second light source chip is disadvantageously increased due to excessive heating. Consequently, luminous characteristics of the second light source chip are disadvantageously decreased, or the life thereof is disadvantageously decreased.

### SUMMARY OF THE INVENTION

A method for manufacturing a semiconductor laser apparatus according to a first aspect of the present invention includes steps of forming a first semiconductor laser device having a first electrode, forming a second semiconductor laser device having a second electrode, forming a first solder layer with a first melting point through a first barrier layer on a third electrode of a base formed with the third electrode and a fourth electrode on a surface thereof, forming a second solder layer with a second melting point through a second barrier layer on the fourth electrode of the base, forming a first reaction solder layer with a third melting point higher than the second melting point by melting the first solder layer with the first melting point to react the first electrode with the first solder layer and bonding the first electrode of the first semiconductor laser device to the third electrode of the base through the first reaction solder layer, and bonding the second electrode of the second semiconductor laser device to the fourth electrode of the base through the second solder layer by applying heat of a first heating temperature to melt the second solder layer with the second melting point lower than the third melting point after the step of bonding the first electrode to the third electrode through the first reaction solder layer.

A semiconductor laser apparatus according to a second aspect of the present invention includes a first semiconductor laser device having a first electrode, a second semiconductor laser device having a second electrode, and a base including a third electrode and a fourth electrode formed on a surface thereof, a first barrier layer formed on the third electrode, and a second barrier layer formed on the fourth electrode, wherein the first electrode of the first semiconductor laser device is bonded to the third electrode of the base through a reaction solder layer formed on the first barrier layer by reacting a first solder layer having a first melting point with the first electrode, the second electrode of the second semiconductor laser device is bonded to the fourth electrode of the base through a second solder layer melted at a second melting point in bonding, and a third melting point of the reaction solder layer is higher than the second melting point of the second solder layer.

An optical apparatus according to a third aspect of the present invention includes the semiconductor laser apparatus according to the second aspect and an optical system controlling a laser beam emitted from the semiconductor laser apparatus.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a top plan view of a two-wavelength semiconductor laser apparatus according to a first embodiment of the present invention;

FIG. 2 is a front elevational view of the two-wavelength semiconductor laser apparatus according to the first embodiment of the present invention, as viewed from a laser beam emitting direction;

FIG. 3 is a top plan view of the two-wavelength semiconductor laser apparatus according to the first embodiment of the present invention in a state where a red semiconductor laser device and a blue-violet semiconductor laser device are removed from a heat radiation substrate;

FIG. 4 is a phase diagram of an Au—Sn alloy for illustrating a composition of a solder layer employed in the two-wavelength semiconductor laser apparatus according to the first embodiment of the present invention;

FIG. 5 is a top plan view for illustrating a manufacturing process for the two-wavelength semiconductor laser apparatus according to the first embodiment of the present invention;

FIG. 6 is a sectional view for illustrating the manufacturing process for the two-wavelength semiconductor laser apparatus according to the first embodiment of the present invention;

FIG. 7 is a diagram for illustrating temporal changes in melting points of solder layers in illustrating the manufacturing process for the two-wavelength semiconductor laser apparatus according to the first embodiment of the present invention;

FIG. 8 is a sectional view for illustrating the manufacturing process for the two-wavelength semiconductor laser apparatus according to the first embodiment of the present invention;

FIG. 9 is a front elevational view of a three-wavelength semiconductor laser apparatus according to a second embodiment of the present invention, as viewed from a laser beam emitting direction;

FIGS. 10 to 12 are sectional views for illustrating a manufacturing process for the three-wavelength semiconductor laser apparatus according to the second embodiment of the present invention; and

FIG. 13 is a schematic diagram showing the structure of an optical pickup according to a third embodiment of the present invention.

### DESCRIPTION OF THE PREFERRED EMBODIMENTS

Embodiments of the present invention are hereinafter described with reference to the drawings.

### First Embodiment

The structure of a two-wavelength semiconductor laser apparatus 100 according to a first embodiment of the present invention is now described with reference to FIGS. 1 to 6. The two-wavelength semiconductor laser apparatus 100 is an example of the “semiconductor laser apparatus” in the present invention.

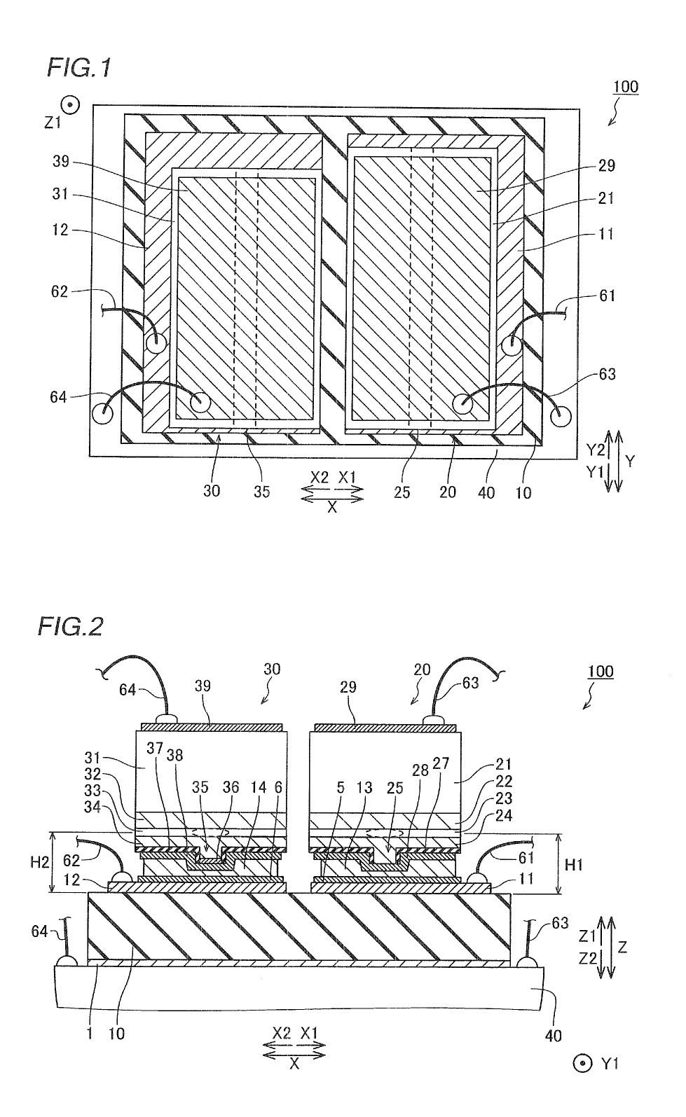

The two-wavelength semiconductor laser apparatus 100 according to the first embodiment of the present invention includes a flat heat radiation substrate 10 having a prescribed thickness, a red semiconductor laser device 20 having a lasing wavelength of about 650 nm and a blue-violet semiconductor laser device 30 having a lasing wavelength of about 405 nm both bonded to the upper surface (on a Z1 side) of the heat radiation substrate 10, and a base portion 40 bonded through a bonding layer 1 (see FIG. 2), supporting the heat radiation substrate 10 from below (a Z2 side), as shown in FIGS. 1 and 2. The heat radiation substrate 10 is an example of the “base” in the present invention. The red semiconductor laser device 20 and the blue-violet semiconductor laser device 30 are examples of the “first semiconductor laser device” and the “second semiconductor laser device” in the present invention, respectively.

As shown in FIG. 2, an electrode 11 arranged on one side (X1 side) in a direction (direction X) orthogonal to an emitting direction (direction Y1) of a laser beam and an electrode 12 arranged on the other side (X2 side) in the direction X are formed on the upper surface of the heat radiation substrate 10 at a prescribed interval. The electrodes 11 and 12 are metal electrodes containing Au and extend in the form of a strip from the front side (Y1 side) to the rear side (Y2 side) of the heat radiation substrate 10, as shown in FIG. 1. The electrodes 11 and 12 are examples of the “third electrode” and the “fourth electrode” in the present invention, respectively.

According to the first embodiment, barrier layers 5 and 6 of Pt are formed on respective surfaces of the electrodes 11 and 12, as shown in FIG. 2. The barrier layers 5 and 6 have thicknesses of about 0.3 μm substantially equal to each other. A p-side electrode 28 of the red semiconductor laser device 20 and the electrode 11 (barrier layer 5) are electrically connected with each other through a reaction solder layer 13. A p-side electrode 38 of the blue-violet semiconductor laser device 30 and the electrode 12 (barrier layer 6) are electrically connected with each other through a reaction solder layer 14. The barrier layers 5 and 6 are examples of the “first barrier layer” and the “second barrier layer” in the present invention, respectively, and the p-side electrodes 28 and 38 are examples of the “first electrode” and the “second electrode” in the present invention, respectively. The reaction solder layers 13 and 14 are examples of the “first reaction solder layer” and the “second reaction solder layer” in the present invention, respectively.

The reaction solder layer 13 is a solder layer made of an Au—Sn alloy containing Au, the content of which is larger than 80 mass %, and Sn, the content of which is smaller than 20 mass %. Specifically, the reaction solder layer 13 is an Au—Sn alloy solder layer formed by reacting (alloying) a solder layer 13a (see FIG. 5) previously formed on the electrode 11 before bonding the red semiconductor laser device 20 to the heat radiation substrate 10 with Au contained in the p-side electrode 28 of the red semiconductor laser device 20 in bonding in a manufacturing process described later. The solder layer 13a before bonding (before heating) is an Au—Sn alloy solder layer containing about 80 mass % Au and about 20 mass % Sn and has a melting point T1 of about 280° C., as shown in FIG. 4. On the other hand, in the reaction solder layer 13 after bonding (after solidification), a melting point T3 of the reaction solder layer 13 is higher than the melting point T1 (a melting point at a eutectic point A of an alloy having a composition of 80 mass % Au and 20 mass % Sn) of the solder layer 13a because the content of Au is increased to more than 80 mass %. In other words, the reaction solder layer 13 is an alloy solder layer in which the content of Au has moved in an increasing direction (left in FIG. 4) from the eutectic point A (melting point T1) to the melting point T3 on a phase diagram in FIG. 4. The barrier layer 5 (see FIG. 5) is provided between the electrode 11 and the reaction solder layer 13, and hence the solder layer 13a and Au contained in the electrode 11 are not alloyed with each other in bonding the red semiconductor laser device 20 to the heat radiation substrate 10. The solder layer 13a is an example of the “first solder layer” in the present invention. The melting point T1 of the solder layer 13a is an example of the “first melting point” in the present invention, and the melting point T3 of the reaction solder layer 13 after bonding (after solidification) is an example of the “third melting point” in the present invention.

The reaction solder layer 14 is a solder layer made of an Au—Sn alloy containing Au, the content of which is larger than 80 mass %, and Sn, the content of which is smaller than 20 mass %. Specifically, the reaction solder layer 14 is an Au—Sn alloy solder layer formed by reacting (alloying) a solder layer 14a (see FIG. 5) previously formed on the electrode 12 before bonding the blue-violet semiconductor laser device 30 to the heat radiation substrate 10 with Au contained in the p-side electrode 38 of the blue-violet semiconductor laser device 30 in bonding in the manufacturing process. The solder layer 14a before bonding (before heating) is an Au—Sn alloy solder layer containing about 80 mass % Au and about 20 mass % Sn and has a melting point T1 of about 280° C. equal to that of the solder layer 13a, as shown in FIG. 4. On the other hand, in the reaction solder layer 14 after bonding (after solidification), a melting point T4 of the reaction solder layer 14 is higher than the melting point T1 (the melting point at the eutectic point A of the alloy having a composition of 80 mass % Au and 20 mass % Sn (see FIG. 4)) of the solder layer 14a because the content of Au is increased to more than 80 mass %. In other words, the reaction solder layer 14 is an alloy solder layer in which the content of Au has moved in the increasing direction (left in FIG. 4) from the eutectic point A (melting point T1) to the melting point T4 on the phase diagram in FIG. 4. The melting point T4 is approximately equal to the melting point T3 of the reaction solder layer 13. The barrier layer 6 (see FIG. 5) is provided between the electrode 12 and the reaction solder layer 14, and hence the solder layer 14a and Au contained in the electrode 12 are not alloyed with each other in bonding the blue-violet semiconductor laser device 30 to the heat radiation substrate 10. The solder layer 14 is an example of the “second solder layer” in the present invention. The melting point T1 of the solder layer 14a is an example of the “second melting point” in the present invention.

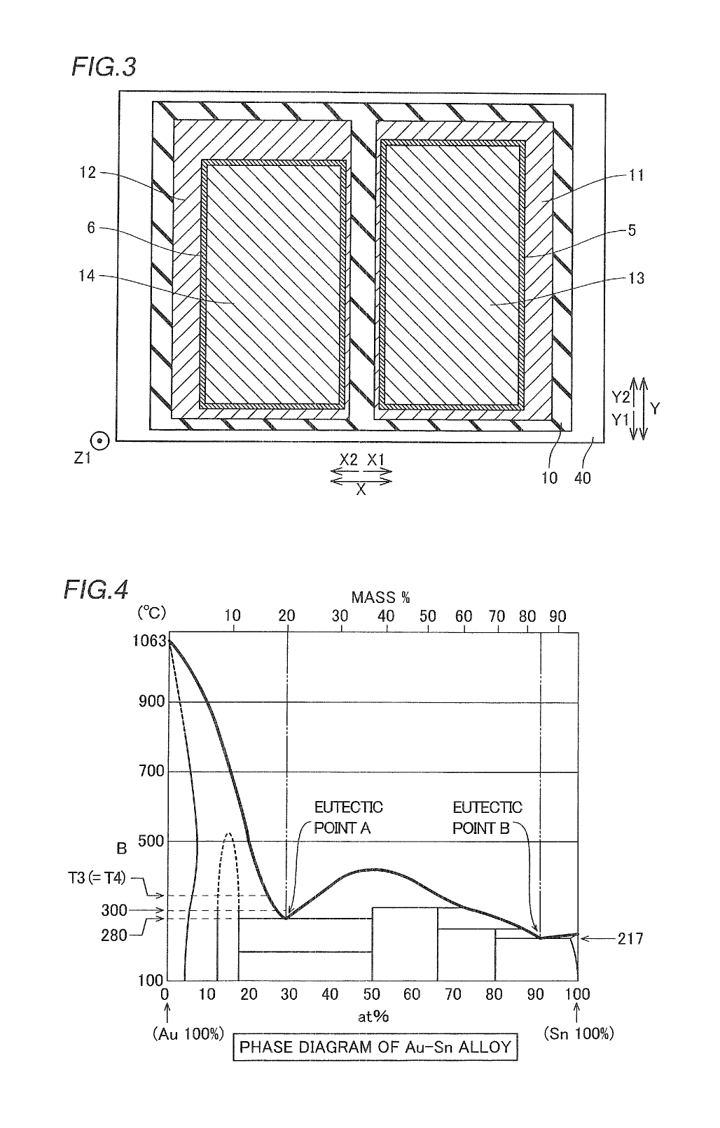

As shown in FIG. 3, an outer edge portion (both end portions in the direction X and both end portions in a direction Y) of the barrier layer 5 is arranged on a region outward beyond an outer edge portion of the reaction solder layer 13. Similarly, an outer edge portion (both end portions in the direction X and both end portions in the direction Y) of the barrier layer 6 is arranged on a region outward beyond an outer edge portion of the reaction solder layer 14. In other words, the plane areas of the barrier layers 5 and 6 are larger than the plane areas of the reaction solder layers 13 and 14, respectively, and the reaction solder layers 13 and 14 are arranged in regions formed with the barrier layers 5 and 6, respectively. Thus, the barrier layer 5 is formed such that the electrode 11 and the reaction solder layer 13 are not in direct contact with each other, and the barrier layer 6 is formed such that the electrode 12 and the reaction solder layer 14 are not in direct contact with each other, as shown in FIG. 2.

The red semiconductor laser device 20 is formed with an n-type cladding layer 22 made of AlGaInP on the lower surface of an n-type GaAs substrate 21, as shown in FIG. 2. An active layer 23 having a multiple quantum well (MQW) structure formed by alternately stacking quantum well layers (not shown) made of GaInP and barrier layers (not shown) made of AlGaInP is formed on the lower surface of the n-type cladding layer 22. A p-type cladding layer 24 made of AlGaInP is formed on the lower surface of the active layer 23.

A ridge portion (projecting portion) 25 extending in the form of a strip along an emitting direction of a laser beam (direction Y1) is formed in the p-type cladding layer 24 in a substantially central portion of the red semiconductor laser device 20 in the width direction (direction X). A current blocking layer 27 made of SiO₂ is formed on the lower surface of the p-type cladding layer 24 other than the ridge portion 25 and the both side surfaces of the ridge portion 25.

The p-side electrode 28 made of Au or the like is formed on the lower surfaces of the ridge portion 25 and the current blocking layer 27. An n-side electrode 29 in which an AuGe layer, a Ni layer, and an Au layer are stacked successively from the side closer to the n-type GaAs substrate 21 is formed on a substantially entire region of the upper surface of the n-type GaAs substrate 21.

The p-side electrode 28 and the upper surface of the heat radiation substrate 10 are bonded to each other, whereby the red semiconductor laser device 20 is bonded to the heat radiation substrate 10 in a junction-down system such that the active layer 23 and the ridge portion 25 are closer to the heat radiation substrate 10 than the n-type GaAs substrate 21. Thus, the height from the upper surface (on the Z1 side) of the heat radiation substrate 10 to the active layer 23 is H1.

The blue-violet semiconductor laser device 30 is formed with an n-type cladding layer 32 made of n-type AlGaN on the lower surface of an n-type GaN substrate 31. An active layer 33 having an MQW structure formed by alternately stacking quantum well layers (not shown) made of InGaN and barrier layers (not shown) made of GaN is formed on the lower surface of the n-type cladding layer 32. A p-type cladding layer 34 made of p-type AlGaN is formed on the lower surface of the active layer 33. The active layer 33 is an example of the “second light-emitting layer” in the present invention.

A ridge portion (projecting portion) 35 extending along the direction Y1 is formed in the p-type cladding layer 34 in a substantially central portion of the blue-violet semiconductor laser device 30 in the direction X. An ohmic electrode 36 in which a Pt layer, a Pd layer, and an Au layer are stacked successively from the side closer to the p-type cladding layer 34 is formed in an upper portion of the ridge portion 35 of the p-type cladding layer 34. A current blocking layer 37 made of SiO₂ is formed on the lower surface of the p-type cladding layer 34 other than the ridge portion 35 and the both side surfaces of the ridge portion 35.

The p-side electrode 38 made of Au or the like is formed on the lower surfaces of the ridge portion 35 and the current blocking layer 37. An n-side electrode 39 in which an Al layer, a Pt layer, and an Au layer are stacked successively from the side closer to the n-type GaN substrate 31 is formed on a substantially entire region of the upper surface of the n-type GaN substrate 31.

The p-side electrode 38 and the upper surface of the heat radiation substrate 10 are bonded to each other, whereby the blue-violet semiconductor laser device 30 is bonded to the heat radiation substrate 10 in a junction-down system such that the active layer 33 and the ridge portion 35 are closer to the heat radiation substrate 10 than the n-type GaN substrate 31. Thus, the height from the upper surface (on the Z1 side) of the heat radiation substrate 10 to the active layer 33 is H2.

The barrier layers 5 and 6 have thicknesses substantially equal to each other, and hence the height H1 from the upper surface of the heat radiation substrate 10 to the active layer 23 of the red semiconductor laser device 20 and the height H2 from the upper surface of the heat radiation substrate 10 to the active layer 33 of the blue-violet semiconductor laser device 30 are substantially equal to each other. Thus, a light-emitting point of the red semiconductor laser device 20 and a light-emitting point of the blue-violet semiconductor laser device 30 are aligned along the width direction (direction X) of the two-wavelength semiconductor laser apparatus 100.

A first end of a metal wire 61 is bonded to a region of the electrode 11 other than a region formed with the barrier layer 5, and a second end of the metal wire 61 is connected to a lead terminal (on an anode side) (not shown). A first end of a metal wire 62 is bonded to a region of the electrode 12 other than a region formed with the barrier layer 6, and a second end of the metal wire 62 is connected to a lead terminal (on the anode side) (not shown). A first end of a metal wire 63 is bonded to the n-side electrode 29 of the red semiconductor laser device 20, and a second end of the metal wire 63 is connected to the base portion 40. A first end of a metal wire 64 is bonded to the n-side electrode 39 of the blue-violet semiconductor laser device 30, and a second end of the metal wire 64 is connected to the base portion 40. The base portion 40 is connected to a cathode terminal (not shown).

A manufacturing process for the two-wavelength semiconductor laser apparatus 100 according to the first embodiment is now described with reference to FIGS. 1 to 8.

As shown in FIGS. 3 and 5, the electrodes 11 and 12 are first formed on the X1 and X2 sides, respectively, on the upper surface of the heat radiation substrate 10. Thereafter, the barrier layer 5 is formed on a surface of the electrode 11 by vacuum evaporation or the like while the barrier layer 6 is formed on a surface of the electrode 12 by vacuum evaporation or the like. The barrier layers 5 and 6 are formed to have thicknesses substantially equal to each other.

Thereafter, the solder layers 13a and 14a are formed on the upper surfaces of the barrier layers 5 and 6, respectively. At this time, the solder layers 13a and 14a are formed such that the outer edge portions thereof are located inward (in the directions X and Y) beyond the outer edge portions of the barrier layers 5 and 6.

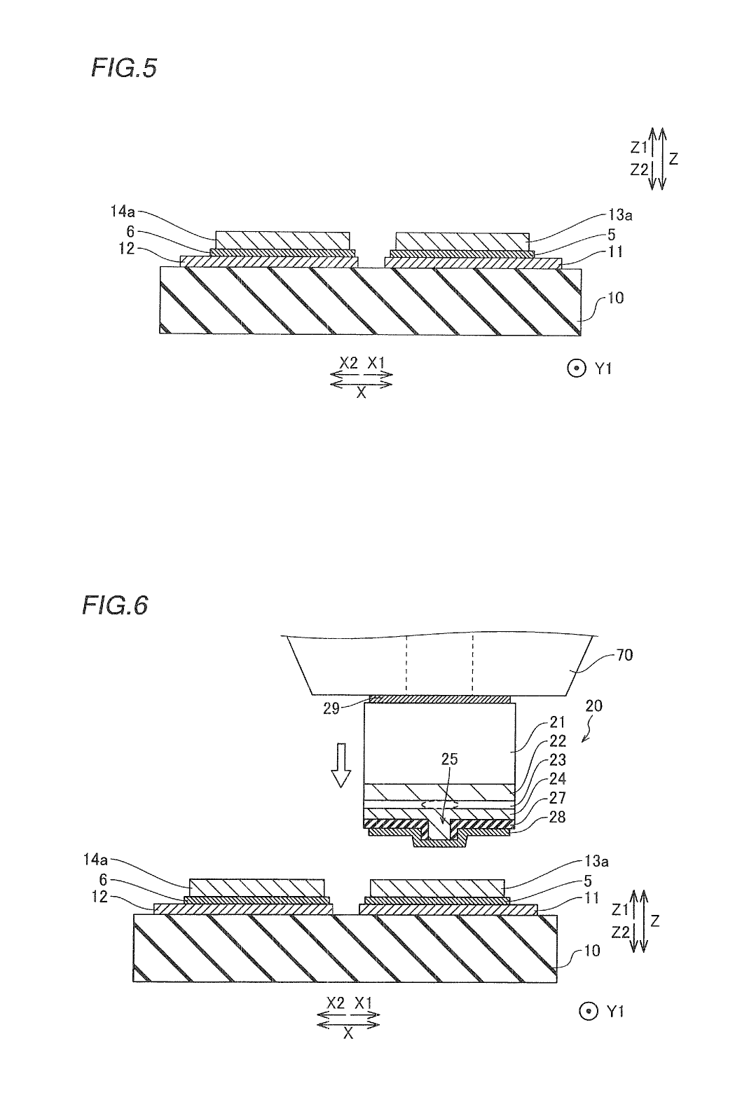

Thereafter, the n-side electrode 29 of the red semiconductor laser device 20 is grasped from above (from the Z1 side) with a collet 70 such that the p-side electrode 28 of the red semiconductor laser device 20 formed through a prescribed manufacturing process and the solder layer 13a are opposed to each other, as shown in FIG. 6. Then, the p-side electrode 28 and the electrode 11 are bonded to each other through the solder layer 13a by moving the collet 70 downward.

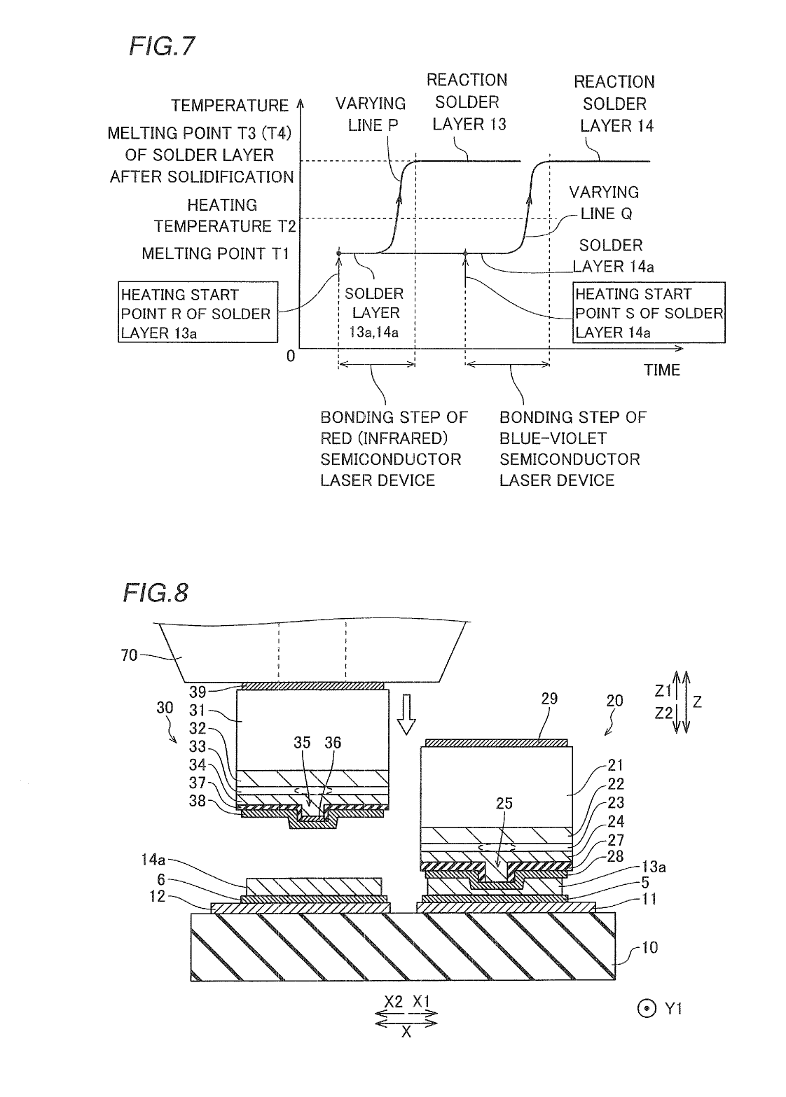

In the manufacturing process of the first embodiment, heat of a heating temperature T2 (about 300° C.) higher than the melting point T1 (about 280° C.) is applied to the solder layer 13a at the timing of a heating start point R, as shown in FIG. 7. At this point, the barrier layer 5 (see FIG. 6) is provided below the solder layer 13a, and hence the solder layer 13a and the electrode 11 are not alloyed with each other. Therefore, the melted solder layer 13a maintains the melting point T1 regardless of elapsed time. Thereafter, in this state, the p-side electrode 28 and the solder layer 13a come into contact with each other, whereby the p-side electrode 28 and the electrode 11 are bonded to each other through the solder layer 13a. At this time, Au contained in the p-side electrode 28 is diffused into the solder layer 13a to alloy the p-side electrode 28 with the solder layer 13a. Thus, the solder layer 13a changes to the reaction solder layer 13 in which the content of Au is relatively increased to more than 80 mass %. In other words, the melting point of the solder layer 13a moves from the melting point T1 to the melting point T3 along a varying line P in a direction of arrow before and after bonding of the red semiconductor laser device 20. Consequently, the melting point T3 of the reaction solder layer 13 after solidification (after bonding) is higher than the melting point T1 (about 280° C.) before alloying of the solder layer 13a with the p-side electrode 28. Further, the melting point T3 is higher than the heating temperature T2 of heat for melting the solder layer 13a applied in bonding. Thus, the p-side electrode 28 of the red semiconductor laser device 20 and the electrode 11 on the heat radiation substrate 10 are bonded to each other. The heating temperature T2 is an example of the “second heating temperature” in the present invention.

In the manufacturing process of the first embodiment, heat is partially applied to the solder layer 14a (see FIG. 6) adjacent to the X2 side of the solder layer 13a when the solder layer 13a is melted, and hence the solder layer 14a is also temporarily melted. However, the barrier layer 6 (see FIG. 6) prevents alloying of the solder layer 14a with the electrode 12 on the heat radiation substrate 10, and hence the composition (a state of the alloy having a composition of 80 mass % Au and 20 mass % Sn) of the solder layer 14a is substantially constant. Therefore, the melting point T1 of the solder layer 14a is substantially constant in melting. In other words, the melted solder layer 14a maintains the melting point T1 when the red semiconductor laser device 20 is bonded to the heat radiation substrate 10, a shown in FIG. 7.

Thereafter, in a state where the reaction solder layer 13 having the melting point T3 is solidified, the n-side electrode 39 of the blue-violet semiconductor laser device 30 is grasped from above (from the Z1 side) with the collet 70 such that the p-side electrode 38 of the blue-violet semiconductor laser device 30 formed through a prescribed manufacturing process and the solder layer 14a are opposed to each other, as shown in FIG. 8. Then, the p-side electrode 38 and the electrode 12 are bonded to each other through the solder layer 14a by moving the collet 70 downward.

In the manufacturing process of the first embodiment, heat having the heating temperature T2 (about 300° C.) set to be higher than the melting point T1 (about 280° C.) and lower than the melting point T3 (T3>300° C.) of the solidified reaction solder layer 13 is applied to the solder layer 14a at the timing of a heating start point S, as shown in FIG. 7. The heating temperature T2 may be set to be lower than a heating temperature in bonding the red semiconductor laser device 20 as long as the same is higher than the melting point T1 of the solder layer 14a. The heating temperature T2 is an example of the “first heating temperature” in the present invention.

Thus, the melting point T1 of the solder layer 14a is substantially constant when the red semiconductor laser device 20 is bonded to the heat radiation substrate 10 (when the solder layer 13a is melted), and hence the solder layer 14a is melted again at the heating temperature T2. At this point, the barrier layer 6 (see FIG. 8) is provided below the solder layer 14a, and hence the solder layer 14a and the electrode 12 are not alloyed with each other. Therefore, the melted solder layer 14a maintains the melting point T1 regardless of elapsed time. Thereafter, in this state, the p-side electrode 38 and the solder layer 14a come into contact with each other, whereby the p-side electrode 38 and the electrode 12 are bonded to each other through the solder layer 14a. At this time, Au contained in the p-side electrode 38 is diffused into the solder layer 14a to alloy the p-side electrode 38 with the solder layer 14a. Thus, the solder layer 14a changes to the reaction solder layer 14 in which the content of Au is relatively increased to more than 80 mass %. In other words, the melting point of the solder layer 14a moves from the melting point T1 to the melting point T4 along a varying line Q in a direction of arrow before and after bonding of the blue-violet semiconductor laser device 30. Consequently, the melting point T4 of the reaction solder layer 14 after solidification is higher than the melting point T1 (about 280° C.) before alloying of the solder layer 14a with the p-side electrode 38. Further, the melting point T4 is higher than the heating temperature T2 of heat for melting the solder layer 14a applied in bonding. In this case, the melting point T4 is approximately equal to the melting point T3 of the solidified reaction solder layer 13. Thus, the p-side electrode 38 of the blue-violet semiconductor laser device 30 and the electrode 12 on the heat radiation substrate 10 are bonded to each other.

In the manufacturing process of the first embodiment, the melting point T3 of the reaction solder layer 13 after alloying (after solidification) is higher than the heating temperature T2 for melting the solder layer 14a (T3>T2), and hence the reaction solder layer 13 is not melted again even if heat is partially applied to the reaction solder layer 13 adjacent to the solder layer 14a in melting the solder layer 14a again. Thus, a bonding position of the red semiconductor laser device 20 previously bonded to the electrode 11 on the heat radiation substrate 10 remains unchanged.

Thereafter, the upper surface of the base portion 40 and the lower surface of the heat radiation substrate 10 are bonded to each other through the bonding layer 1, as shown in FIG. 2. Then, the electrode 11 and the lead terminal (on the anode side) are connected with each other through the metal wire 61, as shown in FIG. 1. The electrode 12 and the lead terminal (on the anode side) are connected with each other through the metal wire 62. The n-side electrode 29 of the red semiconductor laser device 20 and the base portion 40 are connected with each other through the metal wire 63. The n-side electrode 39 of the blue-violet semiconductor laser device 30 and the base portion 40 are connected with each other through the metal wire 64. Thus, the two-wavelength semiconductor laser apparatus 100 is formed.

According to the first embodiment, as hereinabove described, the barrier layer 6 of Pt is previously formed on the surface (on the Z1 side) of the electrode 12 on the heat radiation substrate 10, and the solder layer 14a is formed on the upper surface of the barrier layer 6, whereby the barrier layer 6 lies between the solder layer 14a and the electrode 12 thereby inhibiting direct contact between the solder layer 14a and the electrode 12 even if heat for melting the solder layer 13a with the melting point T1 at the heating start point R (see FIG. 7) is applied to the adjacent solder layer 14a when the p-side electrode 28 of the red semiconductor laser device 20 is bonded to the electrode 11 on the heat radiation substrate 10. Thus, the melting point T1 of the solder layer 14a is prevented from increase, dissimilarly to a case where heat is applied in a state where the solder layer 14a and the electrode 12 are in direct contact with each other thereby alloying the solder layer 14a and the electrode 12 with each other and increasing the melting point of the solder layer 14a when the p-side electrode 28 of the red semiconductor laser device 20 is bonded to the electrode 11 on the heat radiation substrate 10. Consequently, the electrode 12 and the p-side electrode 38 can be bonded to each other by melting the solder layer 14a again at the melting point T1 without setting the heating temperature T2 to a higher temperature when the p-side electrode 38 of the blue-violet semiconductor laser device 30 is bonded to the electrode 12 on the heat radiation substrate 10 to which the red semiconductor laser device 20 is previously bonded. Therefore, excessive heating is not required, and hence thermal stress generated in the blue-violet semiconductor laser device 30 can be inhibited from increase. Consequently, luminous characteristics of the blue-violet semiconductor laser device 30 and the life of the blue-violet semiconductor laser device 30 can be inhibited from decrease when the blue-violet semiconductor laser device 30 is bonded to the heat radiation substrate 10. The barrier layer 6 is made of Pt, and hence alloying of the solder layer 14a with the electrode 12 can be reliably prevented. Thus, the melting point T1 of the solder layer 14a can be reliably prevented from increase when the red semiconductor laser device 20 is bonded to the heat radiation substrate 10.

According to the first embodiment, the barrier layer 5 of Pt is previously formed on the surface (on the Z1 side) of the electrode 11 on the heat radiation substrate 10, and the solder layer 13a is formed on the upper surface of the barrier layer 5, whereby the barrier layer 5 lies between the solder layer 13a and the electrode 11 thereby inhibiting direct contact between the solder layer 13a and the electrode 11 when the p-side electrode 28 of the red semiconductor laser device 20 is bonded to the electrode 11 on the heat radiation substrate 10. Thus, reaction (alloying) of the solder layer 13a with the electrode 11 can be prevented when the solder layer 13a on the side closer to the heat radiation substrate 10 is heated (at the heating start point R in FIG. 7) before the red semiconductor laser device 20 is bonded to the heat radiation substrate 10, and hence the melting point T1 of the solder layer 13a can be maintained in a heating process. Therefore, the melting point T1 is maintained, and hence the p-side electrode 28 of the red semiconductor laser device 20 and the electrode 11 can be easily bonded to each other in a later step without excessive time restriction in the manufacturing process. Further, the barrier layer 5 lies between the solder layer 13a and the electrode 11, and hence the melted solder layer 13a is inhibited from protruding to the electrode 11 beyond the barrier layer 5. Thus, the electrodes 11 and 12 adjacent to each other can be inhibited from short-circuiting by the protruding solder layer 13a. The barrier layer 5 is made of Pt, and hence alloying of the solder layer 13a with the electrode 11 can be reliably prevented at the heating start point R. Thus, the melting point T1 of the solder layer 13a can be reliably prevented from increase when the solder layer 13a is melted at the heating temperature T2.

According to the first embodiment, the heating temperature T2 (about 300° C.) for melting the solder layer 14a again is set to be higher than the melting point T1 (about 280° C.) of the solder layer 14a, whereby the solder layer 14a can be easily melted.

According to the first embodiment, the heating temperature T2 (about 300° C.) is set to be less than the melting point T3 of the reaction solder layer 13 (T2<T3), whereby the reaction solder layer 13 can be inhibited from being melted again even if heat generated in melting the solder layer 14a is applied to the solidified reaction solder layer 13. Thus, the red semiconductor laser device 20 bonded to the heat radiation substrate 10 through the reaction solder layer 13 can be inhibited from deviating from a prescribed bonding position due to the remelted reaction solder layer 13.

According to the first embodiment, the solder layer 13a and the solder layer 14a are formed to have the same melting point T1 (about 280° C.), whereby the barrier layer 6 lying between the solder layer 14a and the electrode 12 can easily inhibit the melting point T1 of the solder layer 14a from increase even if the adjacent solder layer 14a is melted when the red semiconductor laser device 20 is bonded to the heat radiation substrate 10 by melting the solder layer 13a.

According to the first embodiment, the reaction solder layer 13 having the melting point T3 higher than the melting point T1 (about 280° C.) of the solder layer 14a is formed by reacting Au contained in the p-side electrode 28 with the Au—Sn alloy solder layer of the solder layer 13a. Thus, Au contained in the p-side electrode 28 and the Au—Sn alloy of the solder layer 13a are alloyed with each other when the red semiconductor laser device 20 is bonded to the heat radiation substrate 10, and hence the melting point T3 of the reaction solder layer 13 after solidification can be easily rendered higher than the melting point T1 of the solder layer 14a. On the other hand, the melting point T1 of the solder layer 14a remains unchanged due to the barrier layer 6, and hence a difference between the melting point T3 of the reaction solder layer 13 and the melting point T1 of the solder layer 14a can be easily generated.

According to the first embodiment, the heating temperature T2 (about 300° C.) is lower than the melting point T3 of the reaction solder layer 13. The solder layer 13a is melted at about 280° C. employing the heating temperature T2 lower than the melting point T3 and the melted solder layer 13a and the p-side electrode 28 react with each other, whereby the reaction solder layer 13 having the melting point T3 higher than the heating temperature T2 can be formed, and hence the reaction solder layer 13 can be easily formed employing a lower heating temperature.

According to the first embodiment, the heating temperature for bonding the p-side electrode 28 of the red semiconductor laser device 20 to the electrode 11 and the heating temperature for bonding the p-side electrode 38 of the blue-violet semiconductor laser device 30 to the electrode 12 are set to be substantially equal to each other (heating temperature T2). Thus, the blue-violet semiconductor laser device 30 can be bonded to the heat radiation substrate 10 in a later step without changing the heating temperature for bonding the red semiconductor laser device 20 to the heat radiation substrate 10 in a former step. In other words, a change of the heating temperature is not required, and hence the manufacturing process for the two-wavelength semiconductor laser apparatus 100 can be simplified.

According to the first embodiment, the reaction solder layer 13 is solidified to have the melting point T3 in a step of bonding the red semiconductor laser device 20 to the heat radiation substrate 10, and thereafter the blue-violet semiconductor laser device 30 is bonded to the heat radiation substrate 10 (electrode 12) by applying heat of the heating temperature T2. Thus, the blue-violet semiconductor laser device 30 can be bonded to the heat radiation substrate 10 in a state where the reaction solder layer 13 reliably has the melting point T3. Further, the blue-violet semiconductor laser device 30 is bonded in a state where the red semiconductor laser device 20 is reliably bonded to the heat radiation substrate 10 through the solidified reaction solder layer 13, and hence the red semiconductor laser device 20 and the blue-violet semiconductor laser device 30 can be reliably aligned.

According to the first embodiment, the solder layer 14a having the melting point T1 is melted by applying heat of the heating temperature T2, thereby forming the reaction solder layer 14 having the melting point T4 higher than the melting point T1 by reacting the p-side electrode 38 with the solder layer 14a and bonding the p-side electrode 38 to the electrode 12 through the reaction solder layer 14 when the blue-violet semiconductor laser device 30 is bonded to the heat radiation substrate 10 (electrode 12). At this time, the melting point T4 of the reaction solder layer 14 is substantially equal to the melting point T3 of the reaction solder layer 13. Thus, mechanical properties (bonding strengths of solder) of the solidified reaction solder layer 14 having the melting point T4 and the solidified reaction solder layer 13 having the melting point T3 can be kept substantially identical to each other. In other words, the red semiconductor laser device 20 and the blue-violet semiconductor laser device 30 can be bonded onto the heat radiation substrate 10 without generating a difference in bonding strengths of the red semiconductor laser device 20 and the blue-violet semiconductor laser device 30.

According to the first embodiment, the solder layers 13a and 14a each are formed of the Au—Sn alloy solder layer having a composition substantially identical to the composition (the content of Au is about 80 mass %, and the content of Sn is about 20 mass %) of an Au—Sn alloy at the eutectic point (melting point of about 280° C.). Thus, a step of forming the solder layer 13a on the heat radiation substrate 10 and a step of forming the solder layer 14a on the heat radiation substrate 10 can be performed in a single step, and hence the manufacturing process for the two-wavelength semiconductor laser apparatus 100 can be further simplified. Further, a melting point at the eutectic point is lower than melting points of other compositions of an Au—Sn alloy, and hence the melting point of the solder layer 13a and the melting point of the solder layer 14a can be rendered lower than the melting points of other compositions of an Au—Sn alloy. Thus, the heating temperatures T2 for melting the solder layers 13a and 14a can be set to be lower, and hence thermal stress generated in the red semiconductor laser device 20 and the blue-violet semiconductor laser device 30 can be easily inhibited from increase when the red semiconductor laser device 20 and the blue-violet semiconductor laser device 30 are bonded to the heat radiation substrate 10.

According to the first embodiment, the melting points T1 of the solder layers 13a and 14a are temperatures equal or close to the eutectic point of about 280° C. that the Au—Sn alloy in which the content (about 80%) of Au is larger than the content (about 20%) of Sn has. Thus, a temperature difference between the melting point T3 of the reaction solder layer 13 formed by reacting the electrode 11 with the solder layer 13a when bonding the red semiconductor laser device 20 and the melting point T1 of the solder layer 14a before bonding of the blue-violet semiconductor laser device 30 can be clarified by employing the eutectic point of about 280° C. that the Au—Sn alloy in which the content of Au is larger than the content of Sn has, as shown in FIG. 4.

According to the first embodiment, Au contained in the p-side electrode 28 is diffused into the solder layer 13a to alloy with the Au—Sn alloy of the solder layer 13a, whereby the reaction solder layer 13 formed of an Au—Sn alloy reaction solder layer having the melting point T3 higher than the melting point T1 of the solder layer 13a can be easily formed.

According to the first embodiment, the solder layer 13a is formed on the surface of the barrier layer 5 inward beyond the outer edge portion of the barrier layer 5 formed on the electrode 11. Similarly, the solder layer 14a is formed on the surface of the barrier layer 6 inward beyond the outer edge portion of the barrier layer 6 formed on the electrode 12. Thus, the solder layer 13a can be easily formed without contact with the electrode 11, and the solder layer 14a can be easily formed without contact with the electrode 12. Therefore, the solder layers 13a and 14a each melted at the heating temperature T2 in a bonding step can be easily inhibited from reacting with the electrodes 11 and 12, respectively, also when the red semiconductor laser device 20 and the blue-violet semiconductor laser device 30 are bonded to the heat radiation substrate 10.

According to the first embodiment, the thickness of the barrier layer 5 is smaller than the thickness of the electrode 11 and the thickness of the solder layer 13a. Similarly, the thickness of the barrier layer 6 is smaller than the thickness of the electrode 12 and the thickness of the solder layer 14a. Thus, an increase of electric resistance between the electrode 11 and the solder layer 13a can be inhibited while a barrier function of the barrier layer 5 blocking the electrode 11 and the solder layer 13a from each other is maintained. An increase of electric resistance between the electrode 12 and the solder layer 14a can be inhibited while a barrier function of the barrier layer 6 blocking the electrode 12 and the solder layer 14a from each other is maintained.

According to the first embodiment, the blue-violet semiconductor laser device 30 is bonded to the heat radiation substrate 10 after the red semiconductor laser device 20 is bonded to the heat radiation substrate 10, whereby the red semiconductor laser device 20 and the blue-violet semiconductor laser device 30 can be more accurately bonded to prescribed bonding positions on the heat radiation substrate 10 as compared with a case where the red semiconductor laser device 20 and the blue-violet semiconductor laser device 30 are bonded to the heat radiation substrate 10 simultaneously. In general, the blue-violet semiconductor laser device 30 made of a nitride-based semiconductor is more easily influenced by heat in bonding than the red semiconductor laser device 20 made of a GaAs-based semiconductor. Therefore, the number of times for heating the blue-violet semiconductor laser device 30 can be limited to one if the blue-violet semiconductor laser device 30 is bonded after the red semiconductor laser device 20 is previously bonded to the heat radiation substrate 10, and hence heat damage of the blue-violet semiconductor laser device 30 can be effectively inhibited. Further, the heating temperature T2 in bonding is lower than the melting point T3 of the reaction solder layer 13, and hence heat damage of the blue-violet semiconductor laser device 30 can be minimized. Consequently, luminous characteristics of the blue-violet semiconductor laser device 30 can be inhibited from deterioration.

### Second Embodiment

A second embodiment is described with reference to FIGS. 4, 7 and 9 to 12. In a three-wavelength semiconductor laser apparatus 200 according to this second embodiment, a two-wavelength semiconductor laser device 280 made of a red semiconductor laser device 220 and an infrared semiconductor laser device 290 is employed in place of the aforementioned red semiconductor laser device 20 of the first embodiment. The three-wavelength semiconductor laser apparatus 200 is an example of the “semiconductor laser apparatus” in the present invention. In the figures, a structure similar to that of the aforementioned two-wavelength semiconductor laser apparatus 100 according to the first embodiment is denoted by the same reference numerals.

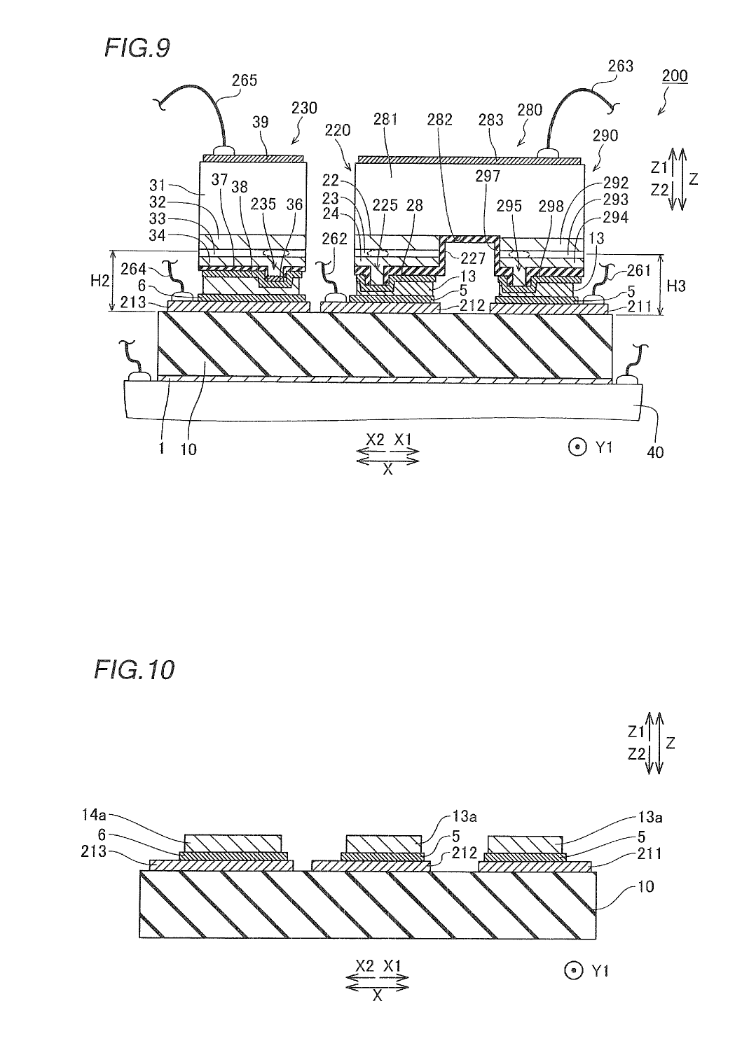

The structure of the three-wavelength semiconductor laser apparatus 200 according to the second embodiment of the present invention is now described with reference to FIG. 9.

The three-wavelength semiconductor laser apparatus 200 according to the second embodiment includes a heat radiation substrate 10, the two-wavelength semiconductor laser device 280 having the red semiconductor laser device 220 with a lasing wavelength of about 650 nm and the infrared semiconductor laser device 290 with a lasing wavelength of about 780 nm monolithically formed on a common GaAs substrate 281, a blue-violet semiconductor laser device 230, and a base portion 40, as shown in FIG. 9. The red semiconductor laser device 220 and the infrared semiconductor laser device 290 are an example of the “first semiconductor laser device” in the present invention. The two-wavelength semiconductor laser device 280 and the blue-violet semiconductor laser device 230 are examples of the “first semiconductor laser device” and the “second semiconductor laser device” in the present invention, respectively.

Electrodes 211, 212, and 213 are formed on the upper surface of the heat radiation substrate 10 in this order from an X1 side to an X2 side. The electrodes 211 to 213 are metal electrodes containing Au and extend in the form of a strip from the front side (Y1 side) to the rear side (Y2 side) of the heat radiation substrate 10. The red semiconductor laser device 220 of the two-wavelength semiconductor laser device 280 is bonded onto the electrode 211a through a reaction solder layer 12. The infrared semiconductor laser device 290 and the red semiconductor laser device 220 of the two-wavelength semiconductor laser device 280 are bonded onto the electrodes 211 and 212 through reaction solder layers 13, respectively. A p-side electrode 38 of the blue-violet semiconductor laser device 230 and the electrode 213 (barrier layer 6) are electrically connected with each other through a reaction solder layer 14. The electrodes 211 and 212 are examples of the “third electrode” in the present invention, and the electrode 213 is an example of the “fourth electrode” in the present invention.

The infrared semiconductor laser device 290 is formed on one side (X1 side) of the lower surface of the n-type GaAs substrate 281, and the red semiconductor laser device 220 is formed on the other side (X2 side) of the lower surface of the n-type GaAs substrate 281. The red semiconductor laser device 220 and the infrared semiconductor laser device 290 are arranged at a prescribed interval through a groove portion 282 formed in a substantially central portion in a direction X.

The red semiconductor laser device 220 is formed with an n-type cladding layer 22, an active layer 23, a p-type cladding layer 24, a current blocking layer 227, and a p-side electrode 28 on the X2 side of the lower surface of the n-type GaAs substrate 281. A ridge portion 225 formed in the p-type cladding layer 24 of the red semiconductor laser device 220 deviates to the blue-violet semiconductor laser device 230 (X2 side) from a central portion of the red semiconductor laser device 220 in the width direction (direction X).

The infrared semiconductor laser device 290 is formed with an n-type cladding layer 292 made of AlGaAs on the X1 side of the lower surface of the n-type GaAs substrate 281. An active layer 293 having an MQW structure formed by alternately stacking quantum well layers made of AlGaAs having a lower Al composition and barrier layers made of AlGaAs having a higher Al composition is formed on the lower surface of the n-type cladding layer 292. A p-type cladding layer 294 made of AlGaAs is formed on the lower surface of the active layer 293.

A ridge portion (projecting portion) 295 extending along an emitting direction of a laser beam (direction Y1) is formed in a portion of the p-type cladding layer 294 deviating to the blue-violet semiconductor laser device 230 (X2 side) from a central portion of the infrared semiconductor laser device 290 in the direction X. A current blocking layer 297 formed integrally with the current blocking layer 227 of the red semiconductor laser device 220 is formed on the lower surface of the p-type cladding layer 294 other than the ridge portion 295 and the both side surfaces of the ridge portion 295. A p-side electrode 298 made of Au or the like is formed on the lower surfaces of the ridge portion 295 and the current blocking layer 297. An n-side electrode 283 in which an AuGe layer, a Ni layer, and an Au layer are stacked successively from the side closer to the n-type GaAs substrate 281 is formed on a substantially entire region of the upper surface of the n-type GaAs substrate 281. The p-side electrode 298 is an example of the “first electrode” in the present invention.

The two-wavelength semiconductor laser device 280 is bonded in a junction-down system such that the active layers 23 and 293 are closer to the heat radiation substrate 10 than the n-type GaAs substrate 281 by bonding the p-side electrodes 28 and 298 to the upper surface of the heat radiation substrate 10. Thus, a height from the upper surface (on a Z1 side) of the heat radiation substrate 10 to the active layer 293 is H3.

A ridge portion 235 formed in a p-type cladding layer 34 of the blue-violet semiconductor laser device 230 is formed at a position deviating to the two-wavelength semiconductor laser device 280 (X1 side) from a central portion of the blue-violet semiconductor laser device 230 in the width direction (direction X). Thus, light-emitting points of the blue-violet semiconductor laser device 230 and the two-wavelength semiconductor laser device 280 are gathered at a central portion of the three-wavelength semiconductor laser apparatus 200 in the width direction (direction X).

Barrier layers 5 and 6 have thicknesses substantially equal to each other, and hence the height H3 from the upper surface of the heat radiation substrate 10 to the active layers 23 and 293 of the two-wavelength semiconductor laser device 280 and a height H2 from the upper surface of the heat radiation substrate 10 to the active layer 33 of the blue-violet semiconductor laser device 230 are substantially equal to each other. Thus, the light-emitting points of the two-wavelength semiconductor laser device 280 and the light-emitting point of the blue-violet semiconductor laser device 230 are aligned along the width direction (direction X) of the three-wavelength semiconductor laser apparatus 200.

A first end of a metal wire 261 is bonded to a region of the electrode 211 other than a region formed with the barrier layer 5, and a second end of the metal wire 261 is connected to a lead terminal (on an anode side) (not shown). A first end of a metal wire 262 is bonded to a region of the electrode 212 other than a region formed with the barrier layer 5, and a second end of the metal wire 262 is connected to a lead terminal (on the anode side) (not shown). A first end of a metal wire 263 is bonded to the n-side electrode 283 of the two-wavelength semiconductor laser device 280, and a second end of the metal wire 263 is connected to the base portion 40. A first end of a metal wire 264 is bonded to the electrode 213, and a second end of the metal wire 264 is connected to a lead terminal (on the anode side) (not shown). A first end of a metal wire 265 is bonded to an n-side electrode 39 of the blue-violet semiconductor laser device 230, and a second end of the metal wire 265 is connected to the base portion 40.

The remaining structure of the three-wavelength semiconductor laser apparatus 200 according to the second embodiment is similar to that of the aforementioned two-wavelength semiconductor laser apparatus 100 according to the first embodiment.

A manufacturing process for the three-wavelength semiconductor laser apparatus 200 according to the second embodiment is now described with reference to FIGS. 7 and 9 to 12.

As shown in FIG. 10, the electrodes 211, 212, and 213 are first formed on the upper surface of the heat radiation substrate 10 in this order from the X1 side to the X2 side. Thereafter, the barrier layers 5 are formed on surfaces of the electrodes 211 and 212 by vacuum evaporation or the like while the barrier layer 6 is formed on a surface of the electrode 213 by vacuum evaporation or the like. Then, solder layers 13a and 14a are formed on the upper surfaces of the barrier layers 5 and 6, respectively.

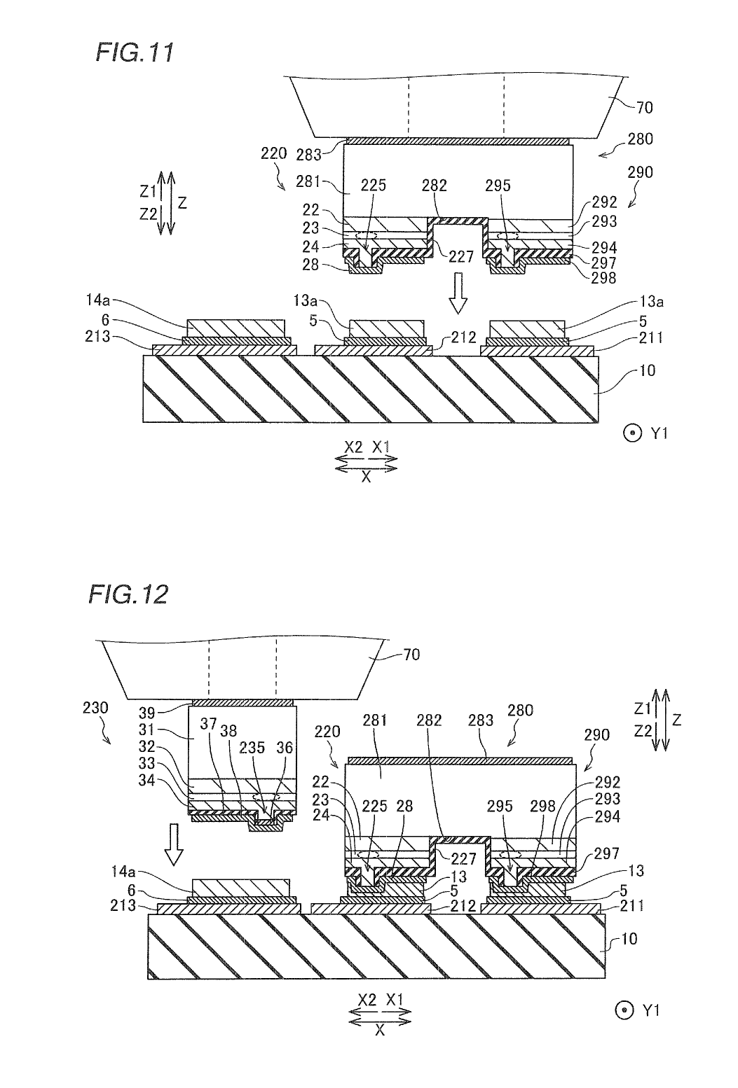

The red semiconductor laser device 220 in which the ridge portion 225 deviates to the side (X2 side) farther from the infrared semiconductor laser device 290 from the center and the infrared semiconductor laser device 290 in which the ridge portion 295 deviates to the red semiconductor laser device 220 (X2 side) from the center are formed on the n-type GaAs substrate 281 through prescribed manufacturing processes, whereby the two-wavelength semiconductor laser device 280 (see FIG. 11) is formed. The blue-violet semiconductor laser device 230 (see FIG. 12) in which the ridge portion 235 deviates to one side from the center is formed through a prescribed manufacturing process.

Thereafter, the n-side electrode 283 of the two-wavelength semiconductor laser device 280 is grasped from above (from the Z1 side) with a collet 70 such that the p-side electrode 28 of the red semiconductor laser device 220 and the solder layer 13a located below are opposed to each other while the p-side electrode 298 of the infrared semiconductor laser device 290 and the solder layer 13a located below are opposed to each other, as shown in FIG. 11. Then, the collet 70 is moved downward, whereby the p-side electrode 28 of the red semiconductor laser device 220 and the electrode 212 are bonded to each other through the solder layer 13a while the p-side electrode 298 of the infrared semiconductor laser device 290 and the electrode 211 are bonded to each other through the solder layer 13a.

In the manufacturing process of the second embodiment, heat of a heating temperature T2 (about 300° C.) higher than the melting point T1 (about 280° C.) of each of the solder layers 13a is applied to the solder layers 13a at the timing of a heating start point R, as shown in FIG. 7. Also in this case, due to the barrier layers 5, the melted solder layers 13a each maintain the melting point T1 regardless of elapsed time. Thereafter, in this state, the p-side electrodes 28 and 298 and the respective solder layers 13a come into contact with each other, whereby the p-side electrodes 28 and 298 are bonded to the electrodes 212 and 211 through the solder layers 13a, respectively. At this time, Au contained in the p-side electrodes 28 and 298 is diffused into the solder layers 13a to alloy the p-side electrodes 28 and 298 with the solder layers 13a. Therefore, the melting point of each of the solder layers 13a moves from the melting point T1 to the melting point T3 along a varying line P in a direction of arrow before and after bonding of the two-wavelength semiconductor laser device 280, as shown in FIG. 7. Thus, the reaction solder layers 13 in which the content of Au is relatively increased to more than 80 mass % are formed.

In the manufacturing process of the second embodiment, heat is partially applied to the solder layer 14a adjacent to the solder layer 13a when the solder layers 13a are melted, and hence the solder layer 14a is also temporarily melted. However, the barrier layer 6 prevents alloying of the solder layer 14a with the electrode 213, and hence the composition (a state of the alloy having a composition of 80 mass % Au and 20 mass % Sn) of the solder layer 14a is substantially constant. Therefore, the melting point T1 of the solder layer 14a is substantially constant. Thus, the melted solder layer 14a maintains the melting point T1 when the two-wavelength semiconductor laser device 280 is bonded to the heat radiation substrate 10, as shown in FIG. 7.

Thereafter, heat of the heating temperature T2 (about 300° C.) is applied to the solder layer 14a again at the timing of a heating start point S (see FIG. 7), as shown in FIG. 12. Thus, the blue-violet semiconductor laser device 230 is bonded to the upper surface of the heat radiation substrate 10 through the remelted solder layer 14a. At this time, the melting point of the solder layer 14a moves from the melting point T1 to the melting point T4 along a varying line Q in a direction of arrow before and after bonding of the blue-violet semiconductor laser device 230, as shown in FIG. 7. Thus, the solder layer 14a changes to a reaction solder layer 14 having the melting point T4 after solidification.

Thereafter, the heat radiation substrate 10 is bonded to the base portion 40 through a bonding layer 1, as shown in FIG. 9. Then, the electrode 211 and the lead terminal (on the anode side) (not shown) are connected with each other through the metal wire 261. The electrode 212 and the lead terminal (on the anode side) (not shown) are connected with each other through the metal wire 262. The n-side electrode 283 and the base portion 40 are connected with each other through the metal wire 263. The electrode 213 and the lead terminal (on the anode side) (not shown) are connected with each other through the metal wire 264. The n-side electrode 39 and the base portion 40 are connected with each other through the metal wire 265.

The remaining manufacturing process for the three-wavelength semiconductor laser apparatus 200 according to the second embodiment is similar to the aforementioned manufacturing process for the two-wavelength semiconductor laser apparatus 100 according to the first embodiment.

According to the second embodiment, as hereinabove described, the barrier layer 6 is formed on the surface (Z1 side) of the electrode 213 on the heat radiation substrate 10, and the solder layer 14a is formed on the upper surface of the barrier layer 6 in a case where the three-wavelength semiconductor laser apparatus 200 includes the two-wavelength semiconductor laser device 280 having the red semiconductor laser device 220 and the infrared semiconductor laser device 290 monolithically formed and the blue-violet semiconductor laser device 230. Thus, the barrier layer 6 lying between the solder layer 14a and the electrode 213 inhibits direct contact between the solder layer 14a and the electrode 213 even if heat for melting the solder layers 13a each having the melting point T1 is applied to the solder layer 14a when the p-side electrodes 28 and 298 of the two-wavelength semiconductor laser device 280 are bonded to the electrodes 212 and 211 on the heat radiation substrate 10, respectively. Thus, the melting point of the solder layer 14a is prevented from increase. Consequently, the electrode 213 and the p-side electrode 38 can be bonded to each other by melting the solder layer 14a again at the melting point T1 without setting the heating temperature T2 to a higher temperature when the p-side electrode 38 of the blue-violet semiconductor laser device 230 is bonded to the electrode 213 on the heat radiation substrate 10 to which the two-wavelength semiconductor laser device 280 is previously bonded. Therefore, luminous characteristics of the blue-violet semiconductor laser device 230 and the life of the blue-violet semiconductor laser device 230 can be inhibited from decrease.

According to the second embodiment, the barrier layers 5 and 6 have thicknesses substantially equal to each other, and hence the height H3 from the upper surface of the heat radiation substrate 10 to the active layers 23 and 293 of the two-wavelength semiconductor laser device 280 and the height H2 from the upper surface of the heat radiation substrate 10 to the active layer 33 of the blue-violet semiconductor laser device 230 are substantially equal to each other. Thus, the light-emitting points of the two-wavelength semiconductor laser device 280 and the light-emitting point of the blue-violet semiconductor laser device 230 can be aligned at the same height, and hence application positions of laser beams from the semiconductor laser devices can be easily aligned also when this three-wavelength semiconductor laser apparatus 200 is built into an optical system such as an optical pickup. The remaining effects of the second embodiment are similar to those of the aforementioned first embodiment.

### Third Embodiment

An optical pickup 300 according to a third embodiment of the present invention is now described with reference to FIGS. 7, 9, 10 and 13. The optical pickup 300 is an example of the “optical apparatus” in the present invention.

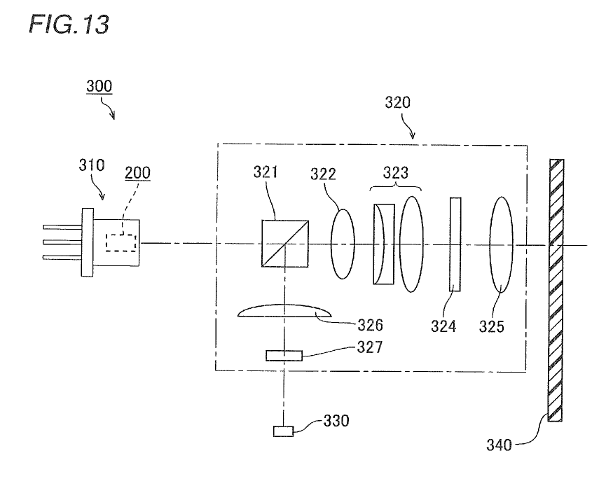

The optical pickup 300 according to the third embodiment of the present invention includes a can-type semiconductor laser apparatus 310 mounted with the aforementioned three-wavelength semiconductor laser apparatus 200 (see FIG. 9) according to the second embodiment, an optical system 320 adjusting laser beams emitted from the semiconductor laser apparatus 310, and a light detection portion 330 receiving the laser beams, as shown in FIG. 13.

The optical system 320 has a polarizing beam splitter (PBS) 321, a collimator lens 322, a beam expander 323, a λ/4 plate 324, an objective lens 325, a cylindrical lens 326, and an optical axis correction device 327.

The PBS 321 totally transmits the laser beams emitted from the semiconductor laser apparatus 310, and totally reflects the laser beams fed back from an optical disc 340. The collimator lens 322 converts the laser beams emitted from the semiconductor laser apparatus 310 and transmitted through the PBS 321 to parallel beams. The beam expander 323 is constituted by a concave lens, a convex lens, and an actuator (not shown). The actuator has a function of correcting wave surface states of the laser beams emitted from the semiconductor laser apparatus 310 by varying a distance between the concave lens and the convex lens.

The λ/4 plate 324 converts the linearly polarized laser beams, converted to the substantially parallel beams by the collimator lens 322, to circularly polarized beams. Further, the λ/4 plate 324 converts the circularly polarized laser beams fed back from the optical disc 340 to linearly polarized beams. A direction of linear polarization in this case is orthogonal to a direction of linear polarization of the laser beams emitted from the semiconductor laser apparatus 310. Thus, the PBS 321 substantially totally reflects the laser beams fed back from the optical disc 340. The objective lens 325 converges the laser beams transmitted through the λ/4 plate 324 on a surface (recording layer) of the optical disc 340. An objective lens actuator (not shown) renders the objective lens 325 movable.

The cylindrical lens 326, the optical axis correction device 327, and the light detection portion 330 are arranged to be along optical axes of the laser beams totally reflected by the PBS 321. The cylindrical lens 326 provides the incident laser beams with astigmatic action. The optical axis correction device 327 is constituted by a diffraction grating and so arranged that spots of zero-order diffracted beams of blue-violet, red, and infrared laser beams transmitted through the cylindrical lens 326 coincide with each other on a detection region of the light detection portion 330 described later.

The light detection portion 330 outputs a playback signal on the basis of intensity distribution of the received laser beams. Thus, the optical pickup 300 including the semiconductor laser apparatus 310 is formed.

In this optical pickup 300, the semiconductor laser apparatus 310 can independently emit red, blue-violet, and infrared laser beams from the red semiconductor laser device 220, the blue-violet semiconductor laser device 230, and the infrared semiconductor laser device 290 (see FIG. 9). The laser beams emitted from the semiconductor laser apparatus 310 are adjusted by the PBS 321, the collimator lens 322, the beam expander 323, the λ/4 plate 324, the objective lens 325, the cylindrical lens 326, and the optical axis correction device 327 as described above, and thereafter applied onto the detection region of the light detection portion 330.

When data recorded in the optical disc 340 is play backed, the laser beams emitted from the red semiconductor laser device 220, the blue-violet semiconductor laser device 230, and the infrared semiconductor laser device 290 are controlled to have constant power and applied to the recording layer of the optical disc 340, so that the playback signal output from the light detection portion 330 can be obtained. When data is recorded in the optical disc 340, the laser beams emitted from the red semiconductor laser device 220 (infrared semiconductor laser device 290) and the blue-violet semiconductor laser device 230 are controlled in power and applied to the optical disc 340, on the basis of the data to be recorded. Thus, the data can be recorded in the recording layer of the optical disc 340. Thus, the data can be recorded in or played back from the optical disc 340 with the optical pickup 300 including the semiconductor laser apparatus 310.

According to the third embodiment, as hereinabove described, the optical pickup 300 is mounted with the semiconductor laser apparatus 310 including the aforementioned three-wavelength semiconductor laser apparatus 200 according to the second embodiment. Thus, luminous characteristics of the blue-violet semiconductor laser device 230 and the life of the blue-violet semiconductor laser device 230 can be inhibited from decrease. Consequently, the reliable optical pickup 300 having the two-wavelength semiconductor laser device 280 and the blue-violet semiconductor laser device 230 both capable of stably operating and enduring the use for a long time can be obtained. The remaining effects of the third embodiment are similar to those of the aforementioned second embodiment.

Although the present invention has been described and illustrated in detail, it is clearly understood that the same is by way of illustration and example only and is not to be taken by way of limitation, the spirit and scope of the present invention being limited only by the terms of the appended claims.

For example, while the red semiconductor laser device 20 or the two-wavelength semiconductor laser device 280 is bonded to the heat radiation substrate 10, and thereafter the blue-violet semiconductor laser device 30 or 230 is bonded to the heat radiation substrate 10 in each of the aforementioned first and second embodiments, the present invention is not restricted to this. In the present invention, the blue-violet semiconductor laser device 30 or 230 may be bonded to the heat radiation substrate 10, and thereafter the red semiconductor laser device 20 or the two-wavelength semiconductor laser device 280 may be bonded to the heat radiation substrate 10.

While the solder layers 13a and 14a each are formed of the Au—Sn alloy solder layer having a substantially identical composition (the content of Au is about 80 mass %, and the content of Sn is about 20 mass %) in each of the aforementioned first and second embodiments, the present invention is not restricted to this. In the present invention, the solder layers 13a and 14a each may be formed of an Au—Sn alloy solder layer having a different composition. In this case, the melting point of the “first solder layer” in the present invention employed as the semiconductor laser device first bonded to the base is preferably set to be lower than the melting point of the “second solder layer” in the present invention employed as the semiconductor laser device subsequently bonded to the base. Thus, the second solder layer can be inhibited from being easily melted by heat for melting the first solder layer, and hence protrusion of the melted second solder layer to the “fourth electrode” on the base beyond the barrier layer located below can be inhibited. Thus, the third electrode and the fourth electrode can be inhibited from short-circuiting by the second solder layer.

While the p-side electrodes 28 and 38 both contain Au, and the solder layers 13a and 14a each are formed of the Au—Sn alloy solder layer in the aforementioned first embodiment, the present invention is not restricted to this. In the present invention, the p-side electrode 28 may contain metal other than Au, and the first solder layer may be formed of a solder material other than an Au—Sn alloy, as long as the reaction solder layer having the third melting point higher than the second melting point of the second solder layer is formed by reacting the first solder layer with the first electrode.

While the solder layers 13a and 14a each are formed to have a composition substantially identical to the eutectic composition (the Au—Sn alloy in which the content of Au is about 80 mass % and the content of Sn is about 20 mass %) having a melting point of about 280° C. in each of the aforementioned first and second embodiments, the present invention is not restricted to this. In the present invention, the first solder layer and the second solder layer each may be formed to have a composition substantially identical to a composition (the content of Au is about 16 mass %, and the content of Sn is about 84 mass %) of an Au—Sn alloy having a melting point of about 217° C. at a eutectic point B (see FIG. 4). Thus, the first melting point of the first solder layer and the second melting point of the second solder layer can be further decreased. However, the compositions of the first solder layer and the second solder layer are preferably substantially identical to the eutectic composition having a melting point of about 280° C. in which the amount of rise in the melting point to the amount of change in the content of Au is large in order to generate a larger difference between the first melting point of the first solder layer and the third melting point of the reaction solder layer.

While the barrier layers 5 and 6 are made of Pt in each of the aforementioned first and second embodiments, the present invention is not restricted to this. In the present invention, the barrier layers may be made of Ti. Alternatively, the barrier layers may be made of a conductive material such as W, Mo, or Hf other than Pt or Ti, or may be made of at least two of Pt, Ti, W, Mo, and Hf.

While the two-wavelength semiconductor laser apparatus 100 includes the red semiconductor laser device 20 and the blue-violet semiconductor laser device 30 in the aforementioned first embodiment, and the three-wavelength semiconductor laser apparatus 200 includes the two-wavelength semiconductor laser device 280 having the red and infrared semiconductor laser devices and the blue-violet semiconductor laser device 230 in the aforementioned second embodiment, the present invention is not restricted to this. In the present invention, a green semiconductor laser device or a blue semiconductor laser device made of a nitride-based semiconductor may be employed as the “second semiconductor laser device” in the present invention in place of the blue-violet semiconductor laser device. An RGB three-wavelength semiconductor laser apparatus including a red semiconductor laser device, a green semiconductor laser device, and a blue semiconductor laser device may be employed as the three-wavelength semiconductor laser apparatus in the aforementioned second embodiment.

While the semiconductor laser devices are bonded to the heat radiation substrate 10 in a junction-down system in each of the aforementioned first and second embodiments, the present invention is not restricted to this. In the present invention, the semiconductor laser devices may be bonded to the heat radiation substrate 10 in a junction-up system. In this case, the “first electrode” and the “second electrode” in the present invention correspond to the electrodes (n-side electrodes, for example) formed on the surfaces of the opposite sides of the substrates to the active layers.

While the current blocking layers 27, 37, 227, and 297 are made of SiO₂ in the aforementioned first and second embodiments, the present invention is not restricted to this. The current blocking layers may be made of another insulating material such as SiN or a semiconductor material such as AlInP or AlGaN, for example.

While the three-wavelength semiconductor laser apparatus 200 is mounted on the can-type semiconductor laser apparatus 310 in the aforementioned third embodiment, the present invention is not restricted to this. In the present invention, the aforementioned three-wavelength semiconductor laser apparatus 200 according to the second embodiment may be mounted on a frame-type package having a plate-like planar structure, or the aforementioned two-wavelength semiconductor laser apparatus 100 according to the first embodiment may be mounted.

While the optical pickup 300 including the “semiconductor laser apparatus” in the present invention has been shown in the aforementioned third embodiment, the present invention is not restricted to this, but the semiconductor laser apparatus in the present invention may be applied to an optical disc apparatus performing record in an optical disc such as a CD, a DVD, or a BD and playback of the optical disc and an optical apparatus such as a projector.

What is claimed is:

1. A method for manufacturing a semiconductor laser apparatus comprising steps of:
forming a first semiconductor laser device having a first electrode;
forming a second semiconductor laser device having a second electrode;
forming a first solder layer with a first melting point through a first barrier layer on a third electrode of a base formed with said third electrode and a fourth electrode on a surface thereof;
forming a second solder layer with a second melting point through a second barrier layer on said fourth electrode of said base;
forming a first reaction solder layer with a third melting point higher than said second melting point by melting said first solder layer with said first melting point to react said first electrode with said first solder layer, and bonding said first electrode of said first semiconductor laser device to said third electrode of said base through said first reaction solder layer; and
bonding said second electrode of said second semiconductor laser device to said fourth electrode of said base through said second solder layer by applying heat of a first heating temperature to melt said second solder layer with said second melting point lower than said third melting point after said step of bonding said first electrode to said third electrode through said first reaction solder layer.

2. The method for manufacturing a semiconductor laser apparatus according to claim 1, wherein
said first heating temperature is at least said second melting point and less than said third melting point.

3. The method for manufacturing a semiconductor laser apparatus according to claim 1, wherein
said first melting point of said first solder layer is equal or close to said second melting point of said second solder layer and lower than said third melting point of said first reaction solder layer.

4. The method for manufacturing a semiconductor laser apparatus according to claim 1, wherein
said step of bonding said first electrode of said first semiconductor laser device to said third electrode of said base includes a step of forming said first reaction solder layer with said third melting point by melting said first solder layer with said first melting point at a second heating temperature to react said first electrode with said first solder layer, and bonding said first electrode to said third electrode through said first reaction solder layer, and
said second heating temperature is lower than said third melting point of said first reaction solder layer.

5. The method for manufacturing a semiconductor laser apparatus according to claim 1, wherein
said step of bonding said first electrode of said first semiconductor laser device to said third electrode of said base includes a step of forming said first reaction solder layer with said third melting point by melting said first solder layer with said first melting point at a second heating temperature to react said first electrode with said first solder layer, and bonding said first electrode to said third electrode through said first reaction solder layer, and
said first heating temperature is equal or close to said second heating temperature.

6. The method for manufacturing a semiconductor laser apparatus according to claim 1, wherein
said step of bonding said second electrode of said second semiconductor laser device to said fourth electrode of said base includes a step of bonding said second electrode to said fourth electrode by applying heat of said first heating temperature after said first reaction solder layer is solidified to have said third melting point in said step of bonding said first electrode to said third electrode.

7. The method for manufacturing a semiconductor laser apparatus according to claim 1, wherein
said step of bonding said second electrode of said second semiconductor laser device to said fourth electrode of said base includes a step of forming a second reaction solder layer with a fourth melting point higher than said second melting point by applying heat of said first heating temperature and melting said second solder layer with said second melting point to react said second electrode with said second solder layer, and bonding said second electrode to said fourth electrode through said second reaction solder layer.

8. The method for manufacturing a semiconductor laser apparatus according to claim 7, wherein
said fourth melting point of said second reaction solder layer is equal or close to said third melting point of said first reaction solder layer.

9. The method for manufacturing a semiconductor laser apparatus according to claim 1, wherein
at least said first electrode of said first semiconductor laser device contains Au,
said first solder layer with said first melting point and said second solder layer with said second melting point each are formed of an Au—Sn alloy solder layer containing Au and Sn, and
said step of bonding said first electrode of said first semiconductor laser device to said third electrode of said base includes a step of forming said first reaction solder layer with said third melting point higher than said second melting point by reacting said Au contained in said first electrode with said Au—Sn alloy solder layer of said first solder layer.

10. The method for manufacturing a semiconductor laser apparatus according to claim 9, wherein
said first solder layer and said second solder layer each are formed of identical said Au—Sn alloy solder layer having a composition identical or similar to a composition of an Au—Sn alloy at a eutectic point, and
said first reaction solder layer is said Au—Sn alloy solder layer formed after said first melting point, which is a eutectic point of said first solder layer, rises to said third melting point higher than said first melting point.

11. The method for manufacturing a semiconductor laser apparatus according to claim 10, wherein
said first melting point of said first solder layer and said second melting point of said second solder layer are equal or close to the eutectic point of said Au—Sn alloy in which a content of Au is larger than a content of Sn.

12. The method for manufacturing a semiconductor laser apparatus according to claim 9, wherein
said first reaction solder layer formed by reacting said Au in said first electrode with an Au—Sn alloy in said first solder layer has a larger content of Au than said Au—Sn alloy solder layer of said first solder layer and is formed of an Au—Sn alloy reaction solder layer with said third melting point higher than said first melting point of said first solder layer.

13. The method for manufacturing a semiconductor laser apparatus according to claim 1, wherein
said step of forming said first solder layer through said first barrier layer on said third electrode of said base includes a step of forming said first barrier layer on said third electrode and a step of forming said first solder layer on a surface of said first barrier layer inward beyond an outer edge portion of said first barrier layer formed on said third electrode, and
said step of forming said second solder layer through said second barrier layer on said fourth electrode of said base includes a step of forming said second barrier layer on said fourth electrode and a step of forming said second solder layer on a surface of said second barrier layer inward beyond an outer edge portion of said second barrier layer formed on said fourth electrode.

14. The method for manufacturing a semiconductor laser apparatus according to claim 1, wherein
a thickness of said first barrier layer is smaller than a thickness of said third electrode and a thickness of said first solder layer, and
a thickness of said second barrier layer is smaller than a thickness of said fourth electrode and a thickness of said second solder layer.

15. The method for manufacturing a semiconductor laser apparatus according to claim 1, wherein
said first barrier layer and said second barrier layer each are made of at least one of Pt, Ti, W, Mo, and Hf.

16. The method for manufacturing a semiconductor laser apparatus according to claim 1, wherein
said first semiconductor laser device is a semiconductor laser device made of a GaAs-based semiconductor, and
said second semiconductor laser device is a semiconductor laser device made of a nitride-based semiconductor.

17. A semiconductor laser apparatus comprising:
a first semiconductor laser device having a first electrode;
a second semiconductor laser device having a second electrode; and
a base including a third electrode and a fourth electrode formed on a surface thereof, a first barrier layer formed on said third electrode, and a second barrier layer formed on said fourth electrode, wherein
said first electrode of said first semiconductor laser device is bonded to said third electrode of said base through a reaction solder layer formed on said first barrier layer by reacting a first solder layer having a first melting point with said first electrode,
said second electrode of said second semiconductor laser device is bonded to said fourth electrode of said base through a second solder layer melted at a second melting point in bonding, and
a third melting point of said reaction solder layer is higher than said second melting point of said second solder layer.

18. The semiconductor laser apparatus according to claim 17, wherein
said first electrode of said first semiconductor laser device contains Au,
said first solder layer is formed of an Au—Sn alloy solder layer containing Au and Sn, and
said reaction solder layer is said Au—Sn alloy solder layer solidified after a melting point of said Au—Sn alloy solder layer rises from said first melting point to said third melting point higher than said second melting point by reacting said Au contained in said first electrode with said Au—Sn alloy solder layer of said first solder layer.

19. The semiconductor laser apparatus according to claim 17, wherein
a thickness of said first barrier layer and a thickness of said second barrier layer are substantially equal to each other.

20. An optical apparatus comprising:
a semiconductor laser apparatus including a first semiconductor laser device having a first electrode, a second semiconductor laser device having a second electrode, and a base having a third electrode and a fourth electrode formed on a surface thereof, a first barrier layer formed on said third electrode, and a second barrier layer formed on said fourth electrode; and
an optical system controlling a laser beam emitted from said semiconductor laser apparatus, wherein
said first electrode of said first semiconductor laser device is bonded to said third electrode of said base through a reaction solder layer formed on said first barrier layer by reacting a first solder layer having a first melting point with said first electrode,
said second electrode of said second semiconductor laser device is bonded to said fourth electrode of said base through a second solder layer melted at a second melting point in bonding, and
a third melting point of said reaction solder layer is higher than said second melting point of said second solder layer.
